(19) United States
(12) Patent Application Publication
(10) Pub. No.: US 2015/0009488 A1
(43) Pub. Date: Jan. 8, 2015

(54) MASK DISTORTION MEASURING APPARATUS AND METHOD OF MEASURING MASK DISTORTION

(71) Applicant: Kabushiki Kaisha Toshiba, Minato-ku (JP)

(72) Inventors: Yosuke OKAMOTO, Hachioji-shi (JP); Nobuhiro Komine, Nagoya-shi (JP)

(73) Assignee: Kabushiki Kaisha Toshiba, Minato-ku (JP)

(21) Appl. No.: 14/186,114

(22) Filed: Feb. 21, 2014

(30) Foreign Application Priority Data
Jul. 8, 2013 (JP) 2013-142708

(51) Int. Cl. G03F 7/20

(52) U.S. Cl. CPC G03F 7/70616
USPC 356/72

(57) ABSTRACT

According to one embodiment, a mask distortion measuring apparatus is provided, including a light source, a mask holding unit, a projection optical system, an imaging unit, and a distortion calculating unit. The mask holding unit holds masks overlaid with each other. The projection optical system forms a projection image of patterns provided on the masks by irradiating light from the light source to the masks. The imaging unit images the projection image. The distortion calculating unit calculates misalignment of another mask with respect to a mask to be a reference in the masks using the projection image imaged at the imaging unit.

### CROSS-REFERENCE TO RELATED APPLICATIONS

This application is based upon and claims the benefit of priority from Japanese Patent Application No. 2013-142708, filed on Jul. 8, 2013; the entire contents of which are incorporated herein by reference.

### FIELD

Embodiments described herein relate generally to a mask distortion measuring apparatus and a method of measuring mask distortion.

### BACKGROUND

In the process steps of manufacturing a semiconductor device using an exposure system, such processes are repeated in which patterns formed in a front-end of the line are aligned and a pattern is overlaid with the patterns for exposure. At this time, when the alignment accuracy is poor, electrical short circuit defects or open defects occur between an upper layer pattern and an under layer pattern, and the device does not normally operate. The alignment accuracy is determined by mask writing accuracy, the lens performance of an exposure system, stage drive accuracy, and mark coordinates measurement accuracy, for example. In order to improve mask writing accuracy among them, the distortion of written patterns is generally measured and corrected after writing a mask.

However, in previously existing techniques, since it is necessary to measure the absolute coordinates of the written pattern with respect to the mask coordinate system, the accuracy demanded for the lens and stage of a measuring apparatus is considerably high, and a problem arises in that an inspection apparatus becomes expensive.

### BRIEF DESCRIPTION OF THE DRAWINGS

FIG. 1 is a schematic perspective view of an exemplary configuration of a mask distortion measuring apparatus according to a first embodiment;

FIGS. 2A and 2B are plan views of exemplary configurations of a mask and a reference mask;

FIGS. 3A and 3B are schematic diagrams of an exemplary configuration of a mask holding unit;

FIG. 4 is a schematic cross sectional view of another exemplary configuration of the mask distortion measuring apparatus according to the first embodiment;

FIG. 5 is a schematic perspective view of an exemplary configuration of a mask distortion measuring apparatus according to a second embodiment;

FIGS. 6A and 6B are diagrams illustrative of an example in the case where three or more of masks are overlaid; and

FIGS. 7A and 7B are schematic diagrams of manners to measure mask distortion using main body patterns in lines and spaces.

### DETAILED DESCRIPTION

In general, according to one embodiment, a mask distortion measuring apparatus is provided, including a light source, a mask holding unit, a projection optical system, an imaging unit, and a distortion calculating unit. The mask holding unit holds masks overlaid with each other. The projection optical system forms a projection image of patterns provided on the masks by irradiating light from the light source to the masks. The imaging unit images the projection image. The distortion calculating unit calculates misalignment of another mask with respect to a mask to be a reference in the masks using the projection image imaged at the imaging unit.

In the following, a mask distortion measuring apparatus and a method of measuring mask distortion according to embodiments will be described in detail with reference to the accompanying drawings. It is noted that the present invention is not limited to these embodiments.

(First Embodiment)

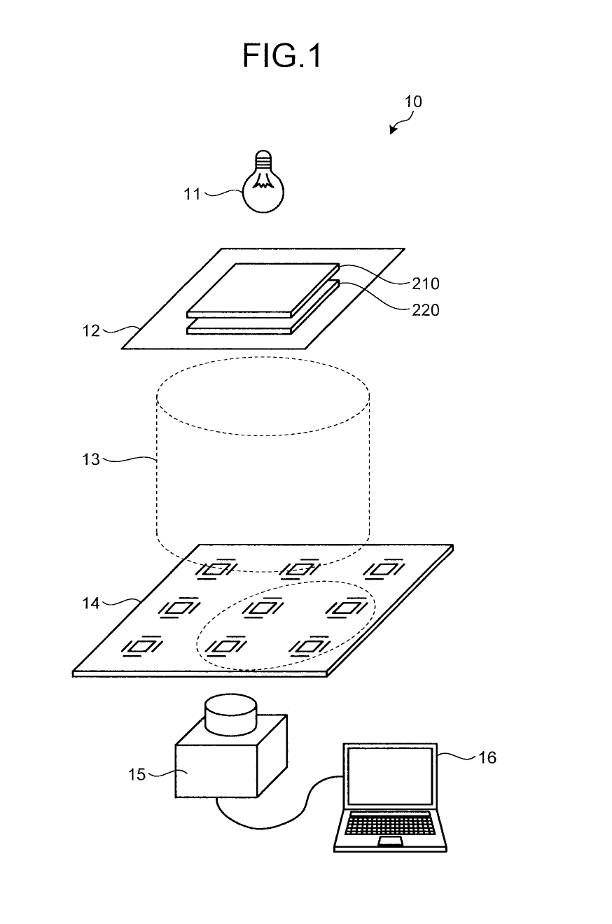

FIG. 1 is a schematic perspective view of an exemplary configuration of a mask distortion measuring apparatus according to a first embodiment. A mask distortion measuring apparatus 10 includes a light source 11, a mask holding unit 12 that holds a mask 210, which is a measurement target, and a reference mask 220, a projection optical system 13 that projects a projection image onto a projection plate 14 in which the projection image is formed by light applied from the light source 11 and transmitted through the mask 210 and the reference mask 220, the projection plate 14 onto which the projection image is projected, the projection image being formed of patterns written on the mask 210 and the reference mask 220 overlaid with each other, an imaging unit 15 that images the projection image projected onto the projection plate 14, and an arithmetic operation processing unit 16 that calculates misalignment of the mask 210 with respect to the reference mask 220 based on the projection image obtained from the imaging unit 15 and determines whether to use the mask 210.

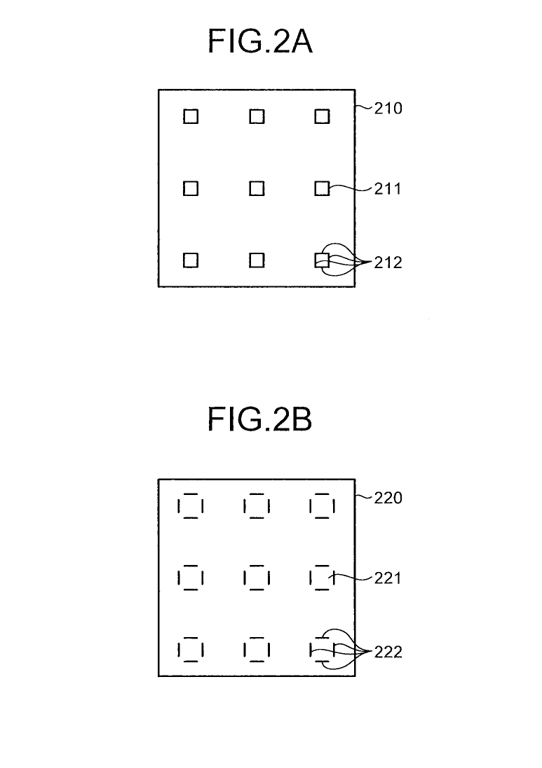

FIGS. 2A and 2B are plan views of exemplary configurations of a mask and a reference mask. As illustrated in FIG. 2A, the mask 210 is provided with patterns, not illustrated, to be transferred on a process target in a manufacturing processes for a semiconductor device and with a misregistration measurement mark 211. The misregistration measurement mark 211 is generally disposed on a region to be a scribe line. Moreover, as illustrated in FIG. 2B, the reference mask 220 is provided with a reference mark 221 to be a reference that measures the misregistration (distortion) of patterns formed on the mask 210. The misregistration measurement mark 211 of the mask 210 is provided at a position on the same coordinates as the coordinates of the reference mark 221 on design. The misregistration measurement mark 211 and the reference mark 221 are provided at predetermined positions on the main surfaces of the mask 210 and the reference mask 220, respectively. The numbers of the misregistration measurement marks 211 and the reference marks 221 are set according to the distortion accuracy of the mask 210, which is desired to acquire.

Moreover, the shapes and sizes of the reference mark 221 and the misregistration measurement mark 211 are not limited as long as the degree of misregistration of the misregistration measurement marks 211 on the mask 210, which is a measurement target, to the reference marks 221 can be measured. For an example, such components can be used in which the reference mark 221 and the misregistration measurement mark 211 are formed of the same components and are disposed at different positions. Furthermore, desirably, all of the reference marks 221 are in the same size and shape, and desirably, all of the misregistration measurement marks 211 are in the same size and shape.

In the example in FIGS. 2A and 2B, the reference mark 221 and the misregistration measurement mark 211 are configured of four bar-shaped marks 212 and 222 in a predetermined length, in which a set of two bar-shaped marks 212 and 222 in parallel with each other is disposed as the extending directions of the bar-shaped marks 212 and 222 are orthogonal to each other. In the misregistration measurement mark 211, four bar-shaped marks 212 are disposed in a square. On the other hand, in the reference mark 221, the bar-shaped marks 222 are disposed in such a way that the spacing between the bar-shaped marks 222 in parallel with each other is greater than the spacing in the case of the misregistration measurement mark 211.

Moreover, the mask 210 and the reference mask 220 are configured of a material transparent to light applied from the light source 11. The mask 210 and the reference mask 220 are disposed as overlaid with each other. However, they may be in intimate contact, or not in intimate contact. Furthermore, the order to overlay the mask 210 with the reference mask 220 is not limited specifically.

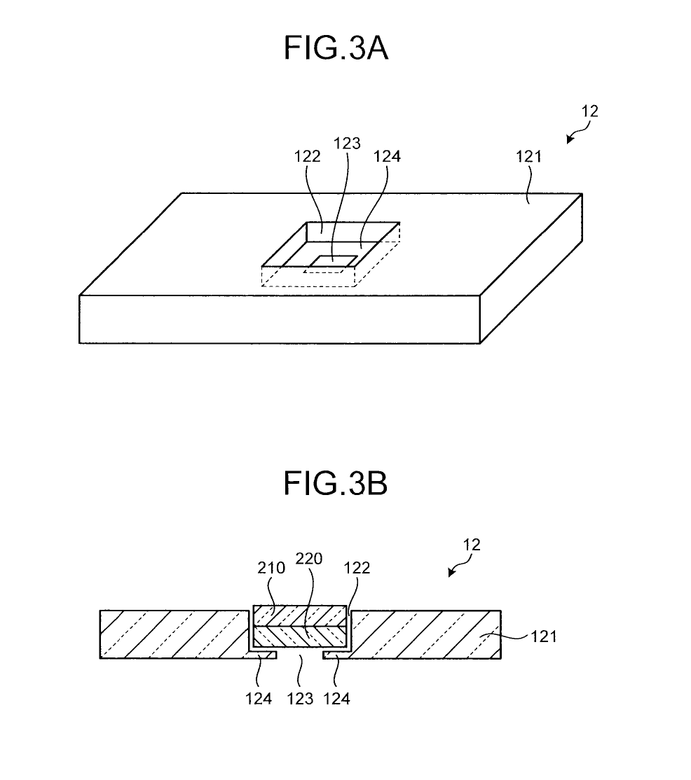

FIGS. 3A and 3B are schematic diagrams of an exemplary configuration of a mask holding unit. FIG. 3A is a schematic perspective view of an exemplary configuration of a mask holding unit, and FIG. 3B is a schematic cross sectional view of the state in which the mask and the reference mask are held on the mask holding unit. As illustrated in FIG. 3A, the mask holding unit 12 is in a structure in which a recessed portion 122 is provided near the center of a mask holding member 121 with a flat plate shape, the area of recessed portion 122 is slightly greater than the areas of the mask 210 and the reference mask 220, and an opening 123 is provided near the center of the bottom portion configuring the recessed portion 122. The mask 210 and the reference mask 220 are disposed on the recessed portion 122 as overlaid with each other.

Moreover, the size of the opening 123 is set in such a way that all of the misregistration measurement marks 211 provided on the mask 210 and all of the reference marks 221 provided on the reference mask 220 are included in the opening 123. Regions other than the opening 123 on the bottom portion configuring the recessed portion 122 function as a mask support portion 124 that supports the mask 210 or the reference mask 220. This mask support portion 124 supports the regions of the peripheral portions of the reference mask 220 or the mask 210, which are not used for forming patterns.

As illustrated in FIG. 3B, in the case where distortion is measured, the reference mask 220 and the mask 210 are disposed on the recessed portion 122 of the mask holding unit 12 as overlaid with each other. The peripheral portion of the reference mask 220 or the mask 210 disposed on the lower side is supported on the mask support portion 124 of the mask holding unit 12, and the mask 210 and the reference mask 220 are fixed to the mask holding unit 12. It is noted that it is unnecessary to overlay the mask 210 with the reference mask 220 in alignment as the misregistration measurement mark 211 is overlaid with the reference mark 221. Moreover, in FIGS. 3A and 3B, the mask 210 is overlaid on the reference mask 220. However, the order may be inverted.

The imaging unit 15 is configured of a CCD (Charge-Coupled Device) image sensor or a CMOS (Complementary Metal-Oxide-Semiconductor) image sensor, for example, and images an image projected onto the projection plate 14.

The arithmetic operation processing unit 16 calculates the positions of the misregistration measurement marks 211 with respect to the reference marks 221 using the projection image imaged at the imaging unit 15, and calculates the degrees of the misregistration (distortion) of the misregistration measurement marks 211. The arithmetic operation processing unit 16 may calculate the degrees of the misregistration in which the arithmetic operation processing unit 16 directly measures a Euclidean distance on the imaged image and converts the Euclidean distance into a distance in a real space or in which the arithmetic operation processing unit 16 converts moire fringes produced by overlaying the marks into a distance in a real space as the distance between the marks. Moreover, the arithmetic operation processing unit 16 also includes a function of determining whether the mask 210, which is a measurement target, is usable in the exposure system from the calculated degree of misregistration. More specifically, the arithmetic operation processing unit 16 determines that the mask 210 is usable in the case where the calculated degree of misregistration can be corrected on the exposure system, whereas the arithmetic operation processing unit 16 determines that the mask 210 is not usable in the case where it is not enabled to correct the calculated degree of misregistration on the exposure system. The arithmetic operation processing unit 16 as described above can be configured using an information processing apparatus, for example.

The patterns on the mask 210 are written with reference to the reference mask 220. Thus, even though the reference mask 220 includes distortion, misalignment does not occur as long as the patterns on the mask 210 are correctly written with respect to the reference mask 220. As described above, the reference mask 220 is a reference for alignment in exposure processing. Thus, in the first embodiment, the positions of the misregistration measurement marks 211 are managed with respect to the reference marks 221 on the reference mask 220. Moreover, the displacement from the positions of the reference marks 221 on the reference mask 220 is only managed, so that it is unnecessary to precisely align the reference mask 220 with the mask 210 in measuring mask distortion.

Next, an example of the procedures of a method for measuring mask distortion in the mask distortion measuring apparatus 10 explained above will be described. This process is performed after fabricating the mask 210 for use in the manufacturing process steps of the semiconductor device.

First, the mask 210, which is a measurement target, immediately after fabricated is carried to the mask distortion measuring apparatus 10, and disposed on the mask holding unit 12 as overlaid with the reference mask 220. Subsequently, when light is applied from the light source 11, the light is transmitted through the mask 210 and the reference mask 220, and a projection image is formed on the projection plate 14, in which the projection image is formed of patterns including the misregistration measurement marks 211 on the mask 210 and the reference marks 221 on the reference mask 220.

The imaging unit 15 images the projection image formed on the projection plate 14. The arithmetic operation processing unit 16 then calculates the misregistration of the misregistration measurement marks 211 on the mask 210 from the reference marks 221 using the imaged image, and calculates distortion information expressing distortion at the positions of the misregistration measurement marks 211 from the misregistration.

After that, the arithmetic operation processing unit 16 uses the distortion information to correct the mask, which is a measurement target, and determines whether the mask is usable. For example, in the case where the distortion information is greater than a predetermined value and it is not enabled to expose a desired pattern even though the distortion of the mask 210 is corrected in exposure processing, the mask 210 is determined as unusable. In this case, the mask 210 is discarded.

On the other hand, in the case where the distortion information is a predetermined value or less and a desired pattern can be exposed by correcting the mask 210 in exposure processing, the mask 210 is determined as usable. In the case where the mask 210 is usable, the mask 210 is for use in manufacture of a semiconductor device (in the exposure process). In this case, the exposure process is performed while correcting the mask 210 using the distortion information. As described above, the processes are ended.

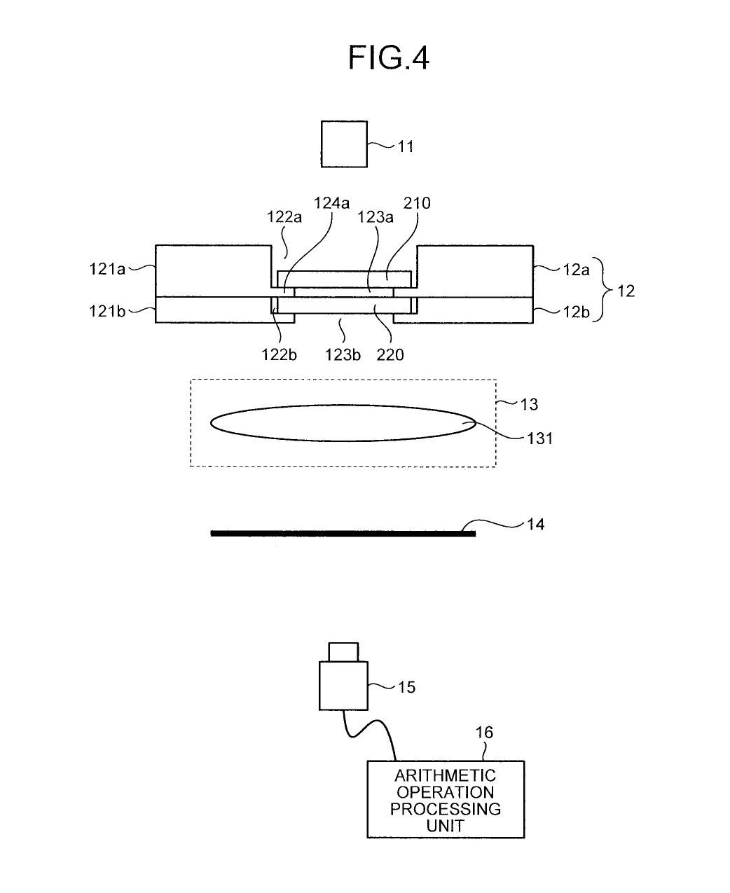

FIG. 4 is a schematic cross sectional view of another exemplary configuration of the mask distortion measuring apparatus according to the first embodiment. In FIG. 4, a mask holding unit 12 that holds the mask 210 and the reference mask 220 is different from the mask holding unit 12 in FIG. 1. Namely, the mask holding unit 12 has a structure in which a mask holding unit 12a that holds the mask 210 is overlaid on a mask holding unit 12b that holds the reference mask 220. The mask holding units 12a and 12b have a structure in which recessed portions 122a and 122b having the area slightly greater than the area of the mask 210 and the reference mask 220 are provided near the center of mask holding members 121a and 121b and openings 123a and 123b are provided near the center of the bottom portion configuring the recessed portions 122a and 122b. The mask 210 is disposed on the recessed portion 122a of the mask holding unit 12a, and the reference mask 220 is disposed on the recessed portion 122b of the mask holding unit 12b.

The mask holding units 12a and 12b are aligned with each other in such a way that the position of the mask 210 is matched with the position of the reference mask 220 when seen in a planar view, and they are overlaid with each other. At this time, a gap is formed between the mask 210 and the reference mask 220 by the thickness of a mask support portion 124a, which is a region other than the opening 123a of the bottom portion configuring the recessed portion 122a of the mask holding unit 12a. It is noted that in FIG. 4, the reference mask 220 is disposed under the mask 210. However, the order of disposing the masks is optional.

Moreover, in FIG. 4, the projection optical system 13 includes a single lens 131. However, the projection optical system 13 is configured of a plurality of lenses. It is noted that the components the same as the components in FIG. 1 are designated the same reference numerals and signs, and the description is omitted.

In the first embodiment, the reference mask 220 is overlaid with the mask 210 on which the misregistration measurement marks 211 are disposed at the positions corresponding to the reference marks 221 on the reference mask 220, and light is irradiated. The projection image formed on the projection plate 14 is then imaged, and the degree of misregistration (distortion information) on the mask 210 with reference to the reference mask 220 is calculated. As described above, it is possible to acquire the distortion information about the mask 210 by a simple method in which the misregistration measurement mark 211 is used for measuring displacement from the reference mark 221 and to determine whether the mask 210 is usable for the exposure process.

Moreover, in the first embodiment, the projection image formed on the projection plate 14 is imaged, and the misregistration of the misregistration measurement mark 211 from the reference mark 221 is measured. Therefore, it is possible to simplify the measurement process as compared with the case where patterns are formed on a resist formed above a substrate to be exposed and the misregistration between alignment marks are measured at a different place later.

(Second Embodiment)

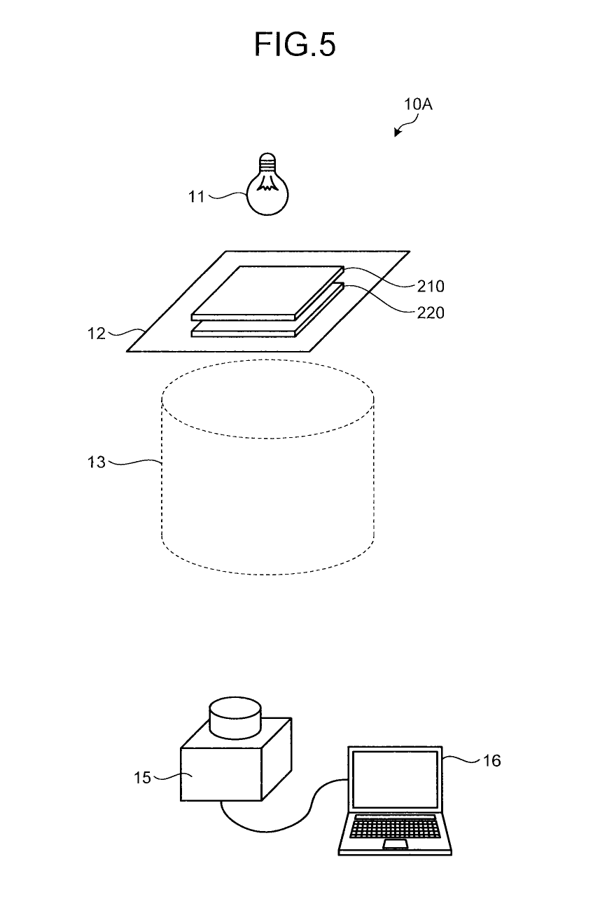

FIG. 5 is a schematic perspective view of an exemplary configuration of a mask distortion measuring apparatus according to a second embodiment. This mask distortion measuring apparatus 10A has a structure in which the projection plate 14 is omitted as compared with the first embodiment. Thus, the configuration of a projection optical system 13 is adjusted or the position of an imaging unit 15 is adjusted in such a way that light transmitted through a mask 210 and a reference mask 220 forms an image on the imaging unit 15. It is noted that components the same as the components in the first embodiment are designated the same reference numerals and signs, and the description is omitted. Moreover, since a method for measuring mask distortion in this mask distortion measuring apparatus 10A is similar to the method in the first embodiment, and the description is omitted.

In the second embodiment, a projection image is formed on the imaging unit 15, so that the effect similar to the first embodiment can be obtained while simplifying the configuration as compared with the first embodiment.

It is noted that in the description above, the case is described where a single mask 210 is overlaid with a single reference mask 220, two masks in total, and the mask distortion is measured. However, the mask distortion may be measured as the mask 210 is overlaid with the reference mask 220 in three masks or more.

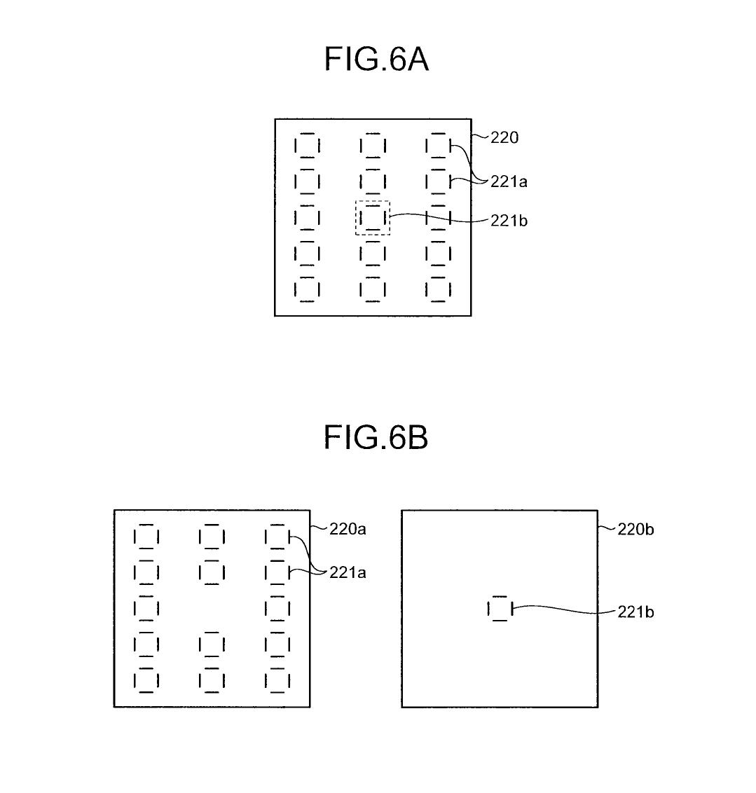

FIG. 6 is a diagram illustrative of an example in the case where three or more of masks are overlaid. FIG. 6A is a reference mask 220 supposed to be generally used, for example. Reference marks 221a and 221b are disposed on this reference mask 220. However, the case can also be considered where the reference mark 221b, which is disposed in the center, for example, is not enabled to be disposed because of the configuration of the reference mask 220. FIG. 6B is the case where two reference masks are used. As illustrated in FIG. 6B, two reference masks may be separately configured of a reference mask 220a on which a reference mark 221b supposed to be disposed in the center is not disposed and other reference marks 221a are disposed and a reference mask 220b on which only a reference mark 221b is disposed in the center. In the case where distortion is then measured, the reference masks 220a and 220b may be overlaid with a mask 210, which is a measurement target.

Moreover, in the description above, the case is shown where the misregistration measurement mark 211 is disposed on the scribe line of the mask 210. However, the disposition is not limited thereto. For example, the misregistration measurement mark 211 may be disposed on a region, in which devices in a chip are not formed, not disposed on the scribe line.

Furthermore, in the description above, the case is shown where the misregistration measurement mark 211 is disposed on the mask 210, the reference mark 221 is disposed on the reference mask 220, and the misregistration of the misregistration measurement mark 211 with respect to the reference mark 221 is measured. However, the embodiment is not limited thereto. For example, it may be possible that main body patterns such as device patterns formed on the mask 210 are used as the misregistration measurement marks 211. In this case, a reference mask 220 may be formed including reference main body patterns formed at the same coordinates as main body patterns on design, a mask 210 is overlaid with the reference mask 220, and distortion information is measured using the mask distortion measuring apparatuses 10 and 10A.

In addition, for example, for the main body patterns, there are cases of using patterns such as devices configuring peripheral circuits or interconnections and using line-and-space patterns formed on a memory cell portion of a NAND flash memory or a ReRAM (Resistive Random Access Memory). In the case of the former, distortion information can be calculated as device patterns are considered to be misregistration measurement patterns by a method similar to the method in the embodiment above.

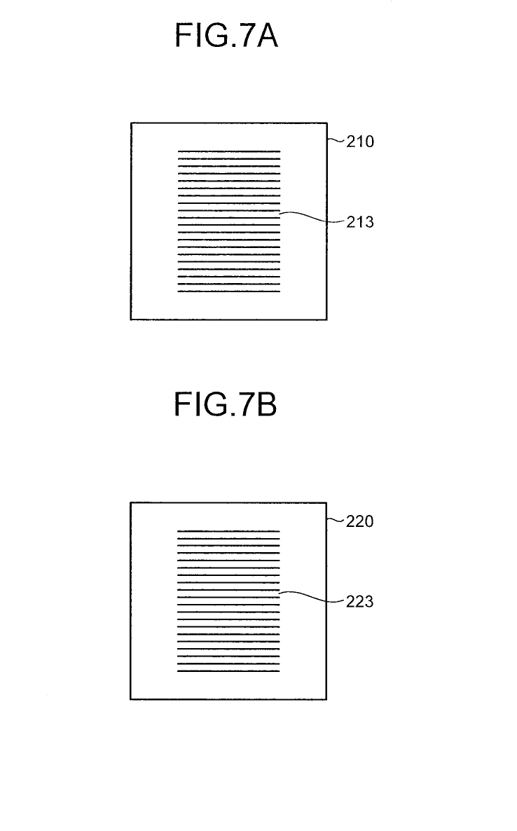

In the case of the latter, a method for calculating distortion information is different from the method in the embodiment above. FIG. 7 is a schematic diagram of manners to measure mask distortion using main body patterns in lines and spaces. A line-and-space pattern 213 is formed on a mask 210. Moreover, a line-and-space pattern 223 is formed as a reference device pattern on a reference mask 220 at the same coordinates as the line-and-space pattern 213 on the mask 210 on design. When these line-and-space patterns 213 and 223 are overlaid with each other on the mask holding unit 12 illustrated in FIG. 1, for example, moire fringes are formed on a projection plate 14. Since the position of distortion, for example, can be calculated backward from the pitch or size of moire fringes, the moire fringes are imaged at the imaging unit 15, the moire fringes are converted into a distance in a real space at the arithmetic operation processing unit 16, and the misregistration (the distortion information) from the reference position is calculated. It is noted that a publicly known method can be used for a method for calculating the position of distortion, for example, using moire fringes, and the description is omitted.

The mask 210 and the reference mask 220 may be transparent to the wavelength of light used at the light source 11. Moreover, the reference mask 220 is not necessarily a mask in the same dimensions and of the same material as the mask 210, which is a measurement target. For example, the reference mask 220 may be a transparent sheet.

Furthermore, in the description above, the case is shown where the imaging unit 15 is disposed below the projection plate 14 when the light source 11 is disposed above the mask holding unit 12. However, the imaging unit 15 may be disposed above the projection plate 14.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A mask distortion measuring apparatus comprising:
a light source;
a mask holding unit configured to hold masks overlaid with each other;
a projection optical system configured to form a projection image of patterns provided on the masks by irradiating light from the light source to the masks;
an imaging unit configured to image the projection image; and
a distortion calculating unit configured to calculate misalignment of another mask with respect to a mask to be a reference in the masks using the projection image imaged at the imaging unit.

2. The mask distortion measuring apparatus according to claim 1, wherein:
one of the masks is a reference mask including a reference mark to be a reference in detecting distortion of a mask which is a measurement target, and one of remaining masks is the mask which is a measurement target, including a misregistration measurement mark provided as corresponding to a position of the reference mark; and
the distortion calculating unit calculates distortion that is misregistration of the misregistration measurement mark of the mask with respect to the reference mark using the projection image imaged at the imaging unit.

3. The mask distortion measuring apparatus according to claim 2, wherein the distortion calculating unit measures a distance between the reference mark and the misregistration measurement mark in the imaged projection image, and calculates the distortion.

4. The mask distortion measuring apparatus according to claim 3, wherein the misregistration measurement mark is a mark disposed at a position other than a position at which a pattern to be transferred to a processing target is formed.

5. The mask distortion measuring apparatus according to claim 4, wherein the misregistration measurement mark is provided on a region corresponding to a scribe line in forming a pattern on the processing target.

6. The mask distortion measuring apparatus according to claim 3, wherein the misregistration measurement mark is a pattern to be transferred to a processing target.

7. The mask distortion measuring apparatus according to claim 2, wherein:
the misregistration measurement mark is a line-and-space pattern to be transferred to a processing target;
the reference mark is a line-and-space pattern provided as corresponding to the misregistration measurement mark; and
the distortion calculating unit calculates the distortion from moire fringes produced by overlaying the reference mark with the misregistration measurement mark in the imaged projection image.

8. The mask distortion measuring apparatus according to claim 2, wherein the mask holding unit holds the reference mask and the mask which is a measurement target, in intimate contact with each other.

9. The mask distortion measuring apparatus according to claim 2, further comprising a projection plate configured to project the projection image onto an image forming surface of the projection optical system,
wherein the imaging unit images an image formed on the projection plate.

10. The mask distortion measuring apparatus according to claim 2, wherein the reference mask is made of a transparent sheet material.

11. A method of measuring mask distortion comprising:
holding masks overlaid with each other;
forming a projection image of patterns provided on the masks by irradiating light from a light source to the masks;
imaging the projection image; and
calculating misalignment of another mask with respect to a mask to be a reference in the masks using the projection image.

12. The method of measuring mask distortion according to claim 11, wherein:
one of the masks is a reference mask including a reference mark to be a reference in detecting distortion of a mask which is a measurement target, and one of remaining masks is the mask which is a measurement target, including a misregistration measurement mark provided as corresponding to a position of the reference mark; and
in the calculating the misalignment, distortion that is misregistration of the misregistration measurement mark of the mask with respect to the reference mark is calculated using the projection image.

13. The method of measuring mask distortion according to claim 12, wherein in the calculating the misalignment, a distance between the reference mark and the misregistration measurement mark in the projection image is measured, and the distortion is calculated.

14. The method of measuring mask distortion according to claim 13, wherein the misregistration measurement mark is a mark disposed at a position other than a position at which a pattern to be transferred to a processing target is formed.

15. The method of measuring mask distortion according to claim 14, wherein the misregistration measurement mark is provided on a region corresponding to a scribe line in forming a pattern on the processing target.

16. The method of measuring mask distortion according to claim 13, wherein the misregistration measurement mark is a pattern to be transferred to a processing target.

17. The method of measuring mask distortion according to claim 12, wherein:
the misregistration measurement mark is a line-and-space pattern to be transferred to a processing target;
the reference mark is a line-and-space pattern provided as corresponding to the misregistration measurement mark; and
in the calculating the misalignment, the distortion is calculated from moire fringes produced by overlaying the reference mark with the misregistration measurement mark in the projection image.

18. The method of measuring mask distortion according to claim 12, wherein the reference mask and the mask which is a measurement target, are held in intimate contact with each other.

19. The method of measuring mask distortion according to claim 12, wherein:
in the forming the projection image, the projection image is projected onto a projection plate; and
in the imaging the projection image, the projection image formed on the projection plate is imaged.

20. The method of measuring mask distortion according to claim 12, wherein the reference mask is formed of a transparent sheet material.
